(19) United States
(12) Patent Application Publication
(10) Pub. No.: US 2026/0068932 A1
(43) Pub. Date: Mar. 12, 2026

(54) AEROSOL-GENERATING DEVICE AND SYSTEM

(71) Applicant: KT&G CORPORATION, Daejeon (KR)

(72) Inventors: Sang Cheol PARK, Suwon-si (KR); Jung Ho KIM, Seoul (KR); Jangwon SEO, Daejeon (KR); Wonkyeong LEE, Guri-si (KR); Chul Ho JANG, Bucheon-si (KR); Jinchul JUNG, Daejeon (KR)

(73) Assignee: KT&G CORPORATION, Daejeon (KR)

(21) Appl. No.: 19/248,707

(22) Filed: Jun. 25, 2025

(30) Foreign Application Priority Data
Sep. 11, 2024 (KR) 10-2024-0123820
Dec. 13, 2024 (KR) 10-2024-0185602

(51) Int. Cl. A24F 40/46; A24F 40/57; H05B 6/80; H05K 1/02

(52) U.S. Cl. CPC A24F 40/46; A24F 40/57; H05B 6/802; H05K 1/0203; H05K 1/0218

(57) ABSTRACT

An aerosol-generating device includes a cavity configured to accommodate an aerosol-generating article, a radiating element, and a printed circuit board. The printed circuit board may include a ground layer, a first dielectric, a second dielectric, a source layer, and a control layer that is separated from the source layer by a gap, and relative permittivity of the first dielectric is less than relative permittivity of the second dielectric.

### CROSS-REFERENCE TO RELATED APPLICATION

This application claims the benefit of Korean Patent Application No. 10-2024-0123820, filed on Sep. 11, 2024, and Korean Patent Application No. 10-2024-0185602, filed on Dec. 13, 2024, in the Korean Intellectual Property Office, the entire disclosures of which are incorporated herein by reference for all purposes.

### BACKGROUND

### 1. Field of the Invention

One or more embodiments relate to an aerosol-generating device and system.

### 2. Description of the Related Art

Technology is being developed to introduce airflow into aerosol-generating articles to implement atomization performance. For example, an aerosol-generating device of a type that generates an aerosol from an aerosol-generating article in a non-combustible manner is being developed. The above description is information the inventor(s) acquired during the course of conceiving the present disclosure, or already possessed at the time, and is not necessarily art publicly known before the present application was filed.

### SUMMARY

Embodiments provide an aerosol-generating device and system with enhanced system stability.

According to an aspect, there is provided an aerosol-generating device including a cavity configured to accommodate an aerosol-generating article, a radiating element configured to radiate a radio frequency (RF) signal to the cavity, and a printed circuit board, wherein the printed circuit board may include a ground layer comprising a first region and a second region that is different from the first region, a first dielectric disposed on the first region, a second dielectric disposed on the second region, a source layer disposed on the first dielectric and having an antenna pattern, and a control layer disposed on the second dielectric, separated from the source layer by a gap, and configured to control the source layer to generate an RF signal, and wherein relative permittivity of the first dielectric may be less than relative permittivity of the second dielectric.

The relative permittivity of the first dielectric may be about 2.0 or more and about 3.5 or less.

The aerosol-generating device may include a heat sink disposed on the source layer.

The heat sink may include graphite.

The aerosol-generating device may include a transmission line configured to connect the source layer to the control layer.

The aerosol-generating device may include a resonance structure at least partially enclosing the cavity.

According to another aspect, there is provided an aerosol-generating system including an aerosol-generating article and an aerosol-generating device configured to heat the aerosol-generating article, wherein the aerosol-generating device may include a cavity configured to accommodate the aerosol-generating article, a radiating element configured to radiate an RF signal to the cavity, and a printed circuit board, wherein the printed circuit board may include a ground layer comprising a first region and a second region that is different from the first region, a first dielectric disposed on the first region, a second dielectric disposed on the second region, a source layer disposed on the first dielectric and having an antenna pattern, and a control layer disposed on the second dielectric, separated from the source layer by a gap, and configured to control the source layer to generate an RF signal, and wherein relative permittivity of the first dielectric may be less than relative permittivity of the second dielectric.

The relative permittivity of the first dielectric may be about 2.0 or more and about 3.5 or less.

The aerosol-generating device may include a heat sink disposed on the source layer.

The heat sink may include graphite.

The aerosol-generating device may include a transmission line configured to connect the source layer to the control layer.

The aerosol-generating device may include a resonance structure at least partially enclosing the cavity.

Additional aspects of embodiments will be set forth in part in the description which follows and, in part, will be apparent from the description, or may be learned by practice of the disclosure.

According to one embodiment, the energy efficiency of an aerosol-generating device and system may be increased. According to one embodiment, the aerosol-generating device and system may increase temperature stability. According to one embodiment, the aerosol-generating device and system may reduce transmission loss. According to one embodiment, the signal transmission performance and/or heating performance of the aerosol-generating device and system may be improved. The effects of the aerosol-generating device and system according to one embodiment are not limited to the above-mentioned effects, and other unmentioned effects may be clearly understood from the following description by one of ordinary skill in the art.

### BRIEF DESCRIPTION OF THE DRAWINGS

These and/or other aspects, features, and advantages of the invention will become apparent and more readily appreciated from the following description of embodiments, taken in conjunction with the accompanying drawings of which:

FIG. 1 is a block diagram of an aerosol-generating device according to one embodiment;

FIG. 2 is a diagram schematically illustrating an aerosol-generating device;

FIG. 3 is a cross-sectional view of a printed circuit board;

FIG. 4 is a cross-sectional view of a printed circuit board and a heat sink; and

FIG. 5 is a cross-sectional view of a printed circuit board and a transmission line.

### DETAILED DESCRIPTION

Hereinafter, the embodiments disclosed in the present specification will be described in detail with reference to the accompanying drawings. The same or similar elements are denoted by the same reference numerals even though they are depicted in different drawings, and redundant descriptions thereof will be omitted. With regard to the description of the drawings, similar reference numerals may be used to refer to similar or related elements.

In the following description, with respect to constituent elements used in the following description, the suffixes “module” and “unit” are used only in consideration of facilitation of description, and do not have mutually distinguished meanings or functions. As used herein, the suffix “module” or “unit” may include a unit implemented in hardware, software, or firmware, and may be used interchangeably with other terms, for example, “logic,” “logic block,” “part,” or “circuitry.” A “module” or a “unit” may be a single integral component, or a minimum unit or part thereof, adapted to perform one or more functions. For example, the “module” or the “unit” may be implemented in the form of an application-specific integrated circuit (ASIC).

In addition, in the following description of the embodiments disclosed in the present specification, a detailed description of known functions and configurations incorporated herein will be omitted when the same may make the subject matter of the embodiments disclosed in the present specification rather unclear. In addition, the accompanying drawings are provided only for a better understanding of the embodiments disclosed in the present specification and are not intended to limit the technical ideas disclosed in the present specification. Therefore, it should be understood that the accompanying drawings include all modifications, equivalents, and substitutions within the scope and spirit of the present disclosure.

It will be understood that although the terms “first”, “second”, etc., may be used herein to describe various components, these components should not be limited by these terms. These terms are only used to distinguish one component from another component.

It will be understood that when a component is referred to as being “connected to” or “coupled to” another component, it may be directly connected to or coupled to another component, or intervening components may be present. On the other hand, when a component is referred to as being “directly connected to” or “directly coupled to” another component, there are no intervening components present.

As used herein, the singular form is intended to include the plural forms as well, unless the context clearly indicates otherwise.

Embodiments as set forth herein may be implemented as software including one or more instructions that are stored in a storage medium (e.g., a memory) that is readable by a machine (e.g., an aerosol-generating device 1). For example, a processor (e.g., a processor 170) of the machine (e.g., the aerosol-generating device 1) may invoke at least one of the one or more instructions stored in the storage medium, and may execute the same. This allows the machine to be operated to perform at least one function according to the at least one instruction invoked. The one or more instructions may include code generated by a compiler or code executable by an interpreter. The machine-readable storage medium may be provided in the form of a non-transitory storage medium. Here, the term “non-transitory” simply means that the storage medium is a tangible device, and does not include a signal (e.g., an electromagnetic wave), but this term does not differentiate between where data is semi-permanently stored in the storage medium and where the data is temporarily stored in the storage medium.

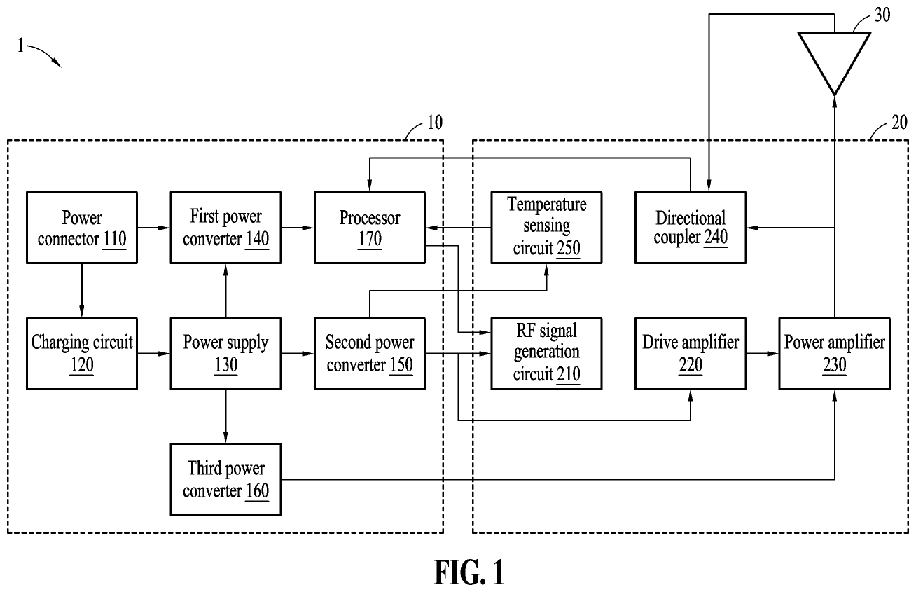

FIG. 1 is a block diagram of the aerosol-generating device 1 according to one embodiment.

According to one embodiment, the aerosol-generating device 1 may include a controller 10, a source unit 20, and a radiating unit 30. The controller 10 may refer to a circuit for controlling the basic operation of the aerosol-generating device 1. The source unit 20 may refer to a circuit for generating a radio frequency (RF) signal under the control of the controller 10. The radiating unit 30 may be a device for radiating the RF signal generated by the source unit 20 into a space into which an aerosol-generating article is inserted (hereinafter, referred to as an insertion space) in the form of an electromagnetic wave. The radiated electromagnetic wave (e.g., the RF signal) may cause electric charges or ions of a dielectric (e.g., glycerin) included in the aerosol-generating article to vibrate or rotate, and the aerosol-generating article may be heated as the dielectric is heated by the frictional heat generated during the process in which the electric charges or ions vibrate or rotate. In other words, the aerosol-generating device 1 may be a device for generating an aerosol by heating the aerosol-generating article using a dielectric heating method.

In one embodiment, the controller 10 may include a power connector 110, a charging circuit 120, a power supply 130, a first power converter 140, a second power converter 150, a third power converter 160, and/or a processor 170. In addition, the source unit 20 may include an RF signal generation circuit 210, a drive amplifier 220, a power amplifier 230, a directional coupler 240, and/or a temperature sensing circuit 250. That is, it will be understood by those skilled in the art related to the present embodiment that some of the components shown in FIG. 1 may be omitted or new components may be further included depending on the design of the aerosol-generating device 1.

The power connector 110 may refer to a physical connection device that is electrically connected to an electronic device or system (e.g., an external power supply) outside the aerosol-generating device 1 and used to transmit and receive power. For example, the power connector 110 may receive power from the external power supply and transfer the received power to a component that needs to be charged (e.g., the power supply 130). The power connector 110 may also provide a path for data transmission. The aerosol-generating device 1 may transmit and receive data to and from an external electronic device or system (e.g., a smartphone, a computer, etc.) via the power connector 110. The power connector 110 may include a universal serial bus (USB) power connector, a direct current (DC) power connector, and the like. In an example, the power connector 110 may be a USB-C type connector for supplying a DC voltage of 9V at a current of 1 A, but is not necessarily limited thereto. The power connector 110 may include an interface for wirelessly transmitting and receiving power.

The charging circuit 120 may refer to a circuit for charging the power supply 130. The charging circuit 120 may charge the power supply 130 using the power received from the power connector 110. In an example, the charging circuit 120 may be implemented as a charger integrated circuit (IC), which is an IC that performs functions to effectively and safely charge the power supply 130. The charging circuit 120 may monitor the voltage, current, and/or temperature of the power supply 130 to monitor the charging state of the power supply 130 or optimize the charging process. For example, the charging circuit 120 may detect the state of the power supply 130, and provide appropriate charging voltage and current to prevent overcharging or overdischarging.

The power supply 130 may supply power for the operation of the aerosol-generating device 1. The power supply 130 may include one or more rechargeable batteries. The power supply 130 may supply power to the radiating unit 30, so that the radiating unit 30 may radiate an electromagnetic wave (e.g., an RF signal) into the insertion space to heat the aerosol-generating article. Here, the supply of power to the radiating unit 30 may have the same meaning as the supply of power to the source unit 20. In addition, the power supply 130 may supply power necessary for the operation of the processor 170, the RF signal generation circuit 210, the drive amplifier 220, the power amplifier 230, the temperature sensing circuit 250, and the like. In an example, the power supply 130 may be lithium polymer (LiPoly) batteries, but is not limited thereto. The power supply 130 may also be replaceable (removable) batteries (hereinafter, detachable batteries). The detachable batteries may be mounted in or removed from a battery receiving unit provided in the aerosol-generating device 1. The detachable batteries may be charged in a wired and/or wireless manner.

The aerosol-generating device 1 may include a power conversion circuit for converting the power supplied from the power supply 130 to a power (e.g., voltage and/or current) appropriate for other components. The power conversion circuit may include at least one of a buck converter, a buck-boost converter, a boost converter, a Zener diode, and a low-dropout (LDO) regulator. In addition, the power conversion circuit may further include, if necessary, a DC/alternating current (AC) converter (e.g., an inverter).

In an example, the aerosol-generating device 1 may include the first power converter 140, the second power converter 150, and the third power converter 160. The first power converter 140 may be an LDO regulator for supplying power (e.g., DC 3.3V) appropriate for the processor 170, the second power converter 150 may be a buck-boost converter for supplying power (e.g., DC 5V) appropriate for the temperature sensing circuit 250, the RF signal generation circuit 210, and the drive amplifier 220, and the third power converter 160 may be a boost converter for supplying power (e.g., DC 12V/25 W) appropriate for the power amplifier 230.

However, the first power converter 140, the second power converter 150, and the third power converter 160 are not limited to the examples described above, and may include other types of power conversion circuits. In addition, although FIG. 1 illustrates the aerosol-generating device 1 including three power converters, the aerosol-generating device 1 may include more or fewer power converters. In an example, at least some of the first power converter 140, the second power converter 150, and the third power converter 160 may be integrated into a single power converter.

The processor 170 may control the overall operation of the aerosol-generating device 1. For example, the processor 170 may directly or indirectly control the charging and discharging of the power supply 130 using the charging circuit 120. In addition, the processor 170 may control the voltage and/or current output by the power conversion circuit by adjusting the frequency and/or duty ratio of current pulses input to at least one switching element of the power conversion circuit. The processor 170 may control the overall operation of the components described later, in addition to the components described above.

The processor 170 may be implemented as an array of multiple logic gates, or may be implemented as a combination of a general-purpose microcontroller unit (MCU) (or microprocessor) and a memory in which a program executable by the MCU is stored. In addition, it will be understood by those skilled in the art to which the present embodiment belongs that the processor 170 may also be implemented as another type of hardware.

The RF signal generation circuit 210 may generate an RF signal based on power received from the power supply 130 or the second power converter 150. The RF signal may refer to a signal having a frequency in the range of 300 megahertz (MHz) to 300 gigahertz (GHz). In an example, the RF signal may have a frequency in the range of 1 GHz to 100 GHz. In addition, the RF signal may have a frequency in the Industrial, Scientific and Medical (ISM) equipment band, such as a frequency of 915 MHz, 2.45 GHZ, and/or 5.8 GHz.

The RF signal generation circuit 210 may include a voltage-controlled oscillator (VCO) that generates an RF signal having a different frequency according to an input voltage. The RF signal generation circuit 210 may receive a control signal (e.g., a DC signal) from the processor 170 and generate an RF signal having a frequency corresponding to the received control signal. The processor 170 may store control signals corresponding to desired frequencies in the form of a look-up table, or may calculate a control signal corresponding to a desired frequency in real time through at least one operation.

In an example, the aerosol-generating device 1 may further include a digital-to-analog converter (D/A converter) for converting a digital control signal output from the processor 170 to an analog control signal. The RF signal generation circuit 210 may receive the analog control signal and generate an RF signal having a frequency corresponding to the received analog control signal.

The drive amplifier 220 may amplify the RF signal generated by the RF signal generation circuit 210. For example, the drive amplifier 220 may amplify the signal level (e.g., the amplitude) of the RF signal, thereby providing an input signal appropriate for a subsequent component (e.g., the power amplifier 230). The drive amplifier 220 may minimize signal distortion by maintaining high linearity. However, the drive amplifier 220 is an amplifier focusing on increasing the signal level and thus may provide relatively low output power.

The power amplifier 230 may amplify the power of the RF signal received from the drive amplifier 220. The power amplifier 230 may be an amplifier focusing on providing sufficient power to a final output device (e.g., the radiating unit 30). For example, the power amplifier 230 may provide an RF signal with high power to the radiating unit 30 such that the radiating unit 30 may radiate an electromagnetic wave into the insertion space to heat the aerosol-generating article. The power amplifier 230 may perform the amplification operation using power received through the third power converter 160 that provides higher power and/or voltage than the second power converter 150.

The drive amplifier 220 and the power amplifier 230 may include transistors such as bipolar junction transistors (BJTs) and field-effect transistors (FETs), or vacuum tubes. In an example, the drive amplifier 220 and the power amplifier 230 may be gallium nitride (GaN) transistors for high-efficient, high-speed, and high-voltage processing, but are not necessarily limited thereto. The drive amplifier 220 and the power amplifier 230 may also include operational amplifiers.

Meanwhile, although FIG. 1 illustrates the drive amplifier 220 and the power amplifier 230 as individual amplifiers, the drive amplifier 220 and the power amplifier 230 may be integrated into a single amplifier. In addition, the drive amplifier 220 and/or the power amplifier 230 may also be configured as a series connection of a plurality of amplifiers, a parallel connection of a plurality of amplifiers, and/or a combination thereof.

The radiating unit 30 may include at least one antenna for radiating an electromagnetic wave into a space. The at least one antenna may have a size and shape suitable for the size and shape of the aerosol-generating article. For example, if the aerosol-generating article is cylindrical, the at least one antenna may be tubular to surround the cylindrical aerosol-generating article. Here, the antenna being tubular may indicate that the antenna is tubular overall. In other words, if the antenna is formed of a metal (e.g., SUS) track, it may indicate the entire track is tubular overall. The shape of the at least one antenna is not limited to the examples described above, and may include various shapes such as a flat plate shape, a curved plate shape, and the like.

The radiating unit 30 may radiate an electromagnetic wave (e.g., the amplified RF signal or transmitted RF signal) into the insertion space to heat the aerosol-generating article. To maximize the heating efficiency of the aerosol-generating article, resonance of the electromagnetic wave needs to occur in the insertion space. The resonance condition (e.g., the resonance frequency) of the insertion space may vary depending on the amount of the dielectric included in the inserted aerosol-generating article. The processor 170 may adjust the control signal input to the RF signal generation circuit 210, thereby controlling the frequency of the RF signal generated by the RF signal generation circuit 210 to correspond to or approximate the resonance condition of the insertion space. The processor 170 may use the directional coupler 240 to obtain information about the resonance condition of the insertion space.

The directional coupler 240 may refer to a passive element having a waveguide structure capable of separating an incident wave and a reflected wave. The directional coupler 240 may separately receive the RF signal transmitted from the power amplifier 230 toward the radiating unit 30 and the electromagnetic wave radiated by the radiating unit 30 and then reflected from the insertion space. The directional coupler 240 may separate the transmitted RF signal and the reflected electromagnetic wave and transfer the transmitted RF signal and the reflected electromagnetic wave to the processor 170.

In an example, the aerosol-generating device 1 may further include an analog-to-digital converter (A/D converter) for converting the analog output of the directional coupler 240 to a digital output. The A/D converter may be embedded in the processor 170, or may be present as a separate component outside the processor 170. The processor 170 may monitor the output of the directional coupler 240 to analyze the characteristics (e.g., the current, voltage, power, phase, and/or frequency) of the transmitted RF signal and the characteristics (e.g., the current, voltage, power, phase, and/or frequency) of the reflected electromagnetic wave.

The processor 170 may verify whether the operation of the source unit 20 is being performed as intended, based on the characteristics of the transmitted RF signal. In addition, the characteristics of the transmitted RF signal may be used, together with the characteristics of the reflected electromagnetic wave, to determine the heating efficiency of the source unit 20 or the radiating unit 30. The processor 170 may control the source unit 20 such that the heating efficiency of the source unit 20 or the radiating unit 30 is maximized. For example, the processor 170 may adjust the frequency of the RF signal generated by the RF signal generation circuit 210 such that the power of the reflected electromagnetic wave may be minimized. The power of the reflected electromagnetic wave being minimized may indicate that the frequency of the RF signal approximates the resonance condition of the insertion space. The characteristics of the transmitted RF signal may provide a reference regarding whether the power of the reflected electromagnetic wave has been minimized.

Since resonance of the electromagnetic wave may occur in the insertion space according to the frequency of the RF signal, the insertion space may be referred to as a resonating unit. At least a portion of the insertion space may be surrounded by at least one shielding member to prevent the electromagnetic wave from leaking to the outside of the aerosol-generating device 1. According to one embodiment, the insertion space may further include a physical structure to cause the resonance condition to fall within a range controllable by the processor 170. The physical structure may include at least one conductor, and the resonance condition of the insertion space may vary depending on the arrangement, thickness, and length of the conductor. In addition, the physical structure may include a space for receiving a dielectric having a low electromagnetic wave absorbance, which is different from the dielectric included in the aerosol-generating article. The dielectric having a low electromagnetic wave absorbance may change the resonance frequency of the entire resonating unit without absorbing energy to be transmitted to an object to be heated. Accordingly, even when the resonating unit is miniaturized, the resonance condition may be determined within the range controllable by the processor 170.

The temperature sensing circuit 250 may be disposed in contact with or adjacent to the components included in the source unit 20 to measure the temperature of the source unit 20. For example, the temperature sensing circuit 250 may be disposed in contact with or adjacent to at least one of the RF signal generation circuit 210, the drive amplifier 220, and the power amplifier 230. During the process of generating and/or amplifying the RF signal, heat may be generated due to limited efficiency, and excessive heat generation may have negative effects on the components included in the source unit 20 or other components included in the aerosol-generating device 1. The temperature measured by the temperature sensing circuit 250 may be used to prevent the source unit 20 from overheating.

The processor 170 may receive the measured temperature (or a value corresponding to the temperature) from the temperature sensing circuit 250, and interrupt the operation of the source unit 20 upon determining that the source unit 20 is overheated. For example, the processor 170 may interrupt the supply of power to the source unit 20 or transmit a control signal, thereby interrupting the operation of the source unit 20. Hereinafter, the expression “supply of power to the source unit 20” is used to indicate control of whether the source unit 20 operates.

The temperature sensing circuit 250 may include at least one of a thermocouple, a resistance temperature detector (RTD), a thermistor, a semiconductor temperature sensor, and an optical temperature sensor. In an example, the temperature sensing circuit 250 may be implemented as a chip-type sensor (e.g., a negative temperature coefficient (NTC) sensor) to minimize the occupied area, but is not necessarily limited thereto.

Meanwhile, the aerosol-generating device 1 may further include components other than the components shown in FIG. 1. For example, the aerosol-generating device 1 may further a sensor unit, an output unit, an input unit, a communication unit, and a memory. In addition, if the aerosol-generating device 1 is a hybrid device that uses both an aerosol-generating article and a cartridge, the aerosol-generating device 1 may further include a cartridge heater. The cartridge heater may receive power from the power supply 130 and heat a medium in the cartridge and/or an aerosol-generating substance.

According to one embodiment, the sensor unit may detect the state of the aerosol-generating device 1 or the state of the surroundings of the aerosol-generating device 1, and may transmit the detected information to the processor 170. For example, the sensor unit may include a temperature sensor, a puff sensor, an insertion detection sensor, a reuse detection sensor, an overly moist state detection sensor, a cigarette identification sensor, a cartridge detection sensor, a cap detection sensor, and/or a movement detection sensor. Meanwhile, the sensor unit may further include various sensors, such as a liquid residual quantity sensor for detecting the residual quantity of liquid in the cartridge and an immersion sensor for detecting immersion of the aerosol-generating device 1.

According to one embodiment, the temperature sensor may detect the temperature of the insertion space or the aerosol-generating article. The temperature sensor may be in contact with or disposed adjacent to the insertion space or the aerosol-generating article and directly measure the temperature of the insertion space or the aerosol-generating article. Alternatively, the temperature sensor may be disposed apart from the insertion space or the aerosol-generating article and indirectly (e.g., contactlessly) measure the temperature of the insertion space or the aerosol-generating article. In an example, the temperature sensor may include an optical temperature sensor (e.g., an infrared temperature sensor).

According to one embodiment, the temperature sensor may detect the temperature of the power supply 130. The temperature sensor may be disposed adjacent to the power supply 130. For example, the temperature sensor may be attached to one surface of the power supply 130 (e.g., a battery) and/or may be mounted on one surface of a printed circuit board. In an example, the aerosol-generating device 1 may include a power supply protection circuit module (PCM), and the temperature sensor may be disposed adjacent to the power supply 130 together with the power supply protection circuit module.

According to one embodiment, the temperature sensor may be disposed in a housing (not shown) of the aerosol-generating device 1 to detect the internal temperature of the housing (not shown).

According to one embodiment, the puff sensor may detect a user's puff.

In an example, the puff sensor may include a pressure sensor. The pressure sensor may output a signal corresponding to the internal pressure of the aerosol-generating device 1, and the processor 170 may determine the user's puff based on the signal corresponding to the internal pressure. Here, the internal pressure of the aerosol-generating device 1 may correspond to the pressure of an airflow path through which gas flows. The puff sensor may be disposed corresponding to the airflow path through which gas flows in the aerosol-generating device 1.

In another example, the puff sensor may include a temperature sensor. When the user's puff occurs, temperature drop may temporarily occur in the airflow path, the insertion space, and the aerosol-generating article. The processor 170 may determine the user's puff based on a signal corresponding to the temperature of the airflow path output from the temperature sensor.

In still another example, the puff sensor may include both a pressure sensor and a temperature sensor. In this case, the temperature sensor may measure temperature used to calibrate the internal pressure measured by the pressure sensor. In one example, the puff sensor may calibrate a signal corresponding to the internal pressure based on the temperature measured by the temperature sensor, and may output the calibrated signal. In another example, the puff sensor may output a signal corresponding to the temperature measured by the temperature sensor and a signal corresponding to the internal pressure measured by the puff sensor. In this case, the processor 170 may receive the signals, and may calibrate the signal corresponding to the internal pressure based on the signal corresponding to the temperature.

In still another example, the puff sensor may include a capacitance sensor. The capacitance sensor may also be called a cap sensor or a capacitive sensor. When the user's puff occurs, a temperature change and/or aerosol flow may occur in the insertion space, and accordingly, a dielectric constant in the insertion space may change. The processor 170 may determine the user's puff based on a signal corresponding to the dielectric constant in the insertion space output from the capacitance sensor.

The puff sensor is not limited to the examples described above, and may be implemented as various sensors for detecting the user's puff.

According to one embodiment, the insertion detection sensor may detect insertion and/or removal of the aerosol-generating article. The insertion detection sensor may be mounted adjacent to the insertion space.

In an example, the insertion detection sensor may include a capacitance sensor. The capacitance sensor may include at least one conductor, and the at least one conductor may be disposed adjacent to the insertion space. When the aerosol-generating article is inserted into or removed from the insertion space, capacitance around the conductor may change. The processor 170 may determine insertion and/or removal of the aerosol-generating article based on a signal corresponding to the dielectric constant in the insertion space output from the capacitance sensor.

In another example, the insertion detection sensor may include an inductive sensor. The inductive sensor may include at least one coil, and the at least one coil may be disposed adjacent to the insertion space. If the aerosol-generating article (e.g., a wrapper of the aerosol-generating article) includes a conductor, when the aerosol-generating article is inserted into or removed from the insertion space, a change in magnetic field may occur around the coil through which current flows. The processor 170 may determine insertion and/or removal of the aerosol-generating article including a conductor based on the characteristics of the current output from or detected by the inductive sensor (e.g., frequency of alternating current, a current value, a voltage value, an inductance value, and an impedance value). Alternatively, a susceptor SUS or the like may be included in the aerosol-generating article (e.g., a medium portion of the aerosol-generating article). In this case, a change in magnetic field may also occur around the coil based on insertion or removal of the susceptor or the like into or from the insertion space, and the processor 170 may determine insertion and/or removal of the aerosol-generating article based on the characteristics of the current of the inductive sensor.

The insertion detection sensor is not limited to the examples described above, and may be implemented as various sensors (e.g., a proximity sensor) for detecting insertion and/or removal of the aerosol-generating article. In addition, the insertion detection sensor may include any combination of the examples described above. According to one embodiment, the insertion detection sensor may include a switch or the like for detecting pressing by the aerosol-generating article.

According to one embodiment, the reuse detection sensor may detect whether the aerosol-generating article is being reused. In an example, the reuse detection sensor may be a color sensor for detecting the color of the aerosol-generating article. If the aerosol-generating article is used by the user, a change in the color of a portion of the wrapper may occur due to the generated aerosol or heating. The color sensor may output a signal corresponding to an optical characteristic (e.g., wavelength of light) corresponding to the color of the wrapper based on the light reflected from the wrapper. When a change in the color of a portion of the wrapper is detected, the processor 170 may determine that the aerosol-generating article inserted into the insertion space has already been used.

According to one embodiment, the overly moist state detection sensor may detect whether the aerosol-generating article is in an overly moist state. For example, the overly moist state detection sensor may include a capacitance sensor. The capacitance sensor may include at least one conductor disposed adjacent to the insertion space. The processor 170 may determine whether the aerosol-generating article is in an overly moist state based on the level of a signal corresponding to the dielectric constant or the like output from the capacitance sensor. In an example, the processor 170 may check a level range within which the level of the signal is included based on a look-up table, and may determine the moisture content of the aerosol-generating article based on the checked level range.

According to one embodiment, the cigarette identification sensor may detect whether the aerosol-generating article is authentic and/or may detect the type of the aerosol-generating article.

In an example, the cigarette identification sensor may include an optical sensor for detecting an identification material (or an identification mark) located on the outer surface (e.g., the wrapper) of the aerosol-generating article. The optical sensor may radiate light toward the identification material (or the identification mark) of the aerosol-generating article, and may detect whether the aerosol-generating article is authentic and/or may detect the type of the aerosol-generating article based on the reflected light. For example, the identification material may include a material (i.e., a luminous material) that emits light of a specific wavelength band based on the light radiated thereto. The processor 170 may determine whether the aerosol-generating article is authentic and/or may determine the type of the aerosol-generating article based on the range of the wavelength.

In another example, the cigarette identification sensor may include a capacitance sensor. The dielectric constant in the insertion space may vary depending on the type of the aerosol-generating article inserted into the insertion space. The processor 170 may determine whether the aerosol-generating article is authentic and/or may determine the type of the aerosol-generating article based on a signal corresponding to the dielectric constant or the like in the insertion space output from the capacitance sensor.

In still another example, the cigarette identification sensor may include an inductive sensor. If a conductor is included in the wrapper and/or inner portion (e.g., the medium portion) of the aerosol-generating article inserted into the insertion space, when the aerosol-generating article is inserted into the insertion space, the characteristics of the current detected by the inductive sensor (e.g., frequency of alternating current, a current value, a voltage value, an inductance value, and an impedance value) may vary depending on the type of the aerosol-generating article inserted into the insertion space. The processor 170 may determine whether the inserted aerosol-generating article is authentic and/or may determine the type of the inserted aerosol-generating article based on the characteristics of the current output from or detected by the inductive sensor.

The cigarette identification sensor is not limited to the examples described above, and may be implemented as various sensors for detecting whether the aerosol-generating article is authentic and/or detecting the type of the aerosol-generating article. In addition, the cigarette identification sensor may include any combination of the examples described above.

According to one embodiment, the cartridge detection sensor may detect mounting and/or removal of the cartridge. For example, the cartridge detection sensor may include an inductive sensor, a capacitance sensor, a resistance sensor, a Hall sensor (Hall IC), and/or an optical sensor.

According to one embodiment, the cap detection sensor may detect mounting and/or removal of the cap. For example, the cap detection sensor may include an inductive sensor, a capacitance sensor, a resistance sensor, a contact sensor, a Hall sensor (Hall IC), and/or an optical sensor. The cap may cover at least a portion of the cartridge mounted in or inserted into the aerosol-generating device 1 or may cover at least a portion of the housing of the aerosol-generating device 1. When the cap is mounted in or removed from the housing, the cap detection sensor may output a signal corresponding to mounting or removal, and the processor 170 may determine mounting or removal of the cap based on the signal corresponding to mounting or removal.

According to one embodiment, the movement detection sensor may detect movement of the aerosol-generating device 1. The movement detection sensor may be implemented as at least one of an acceleration sensor or a gyro sensor.

According to one embodiment, the sensor unit may further include at least one of a humidity sensor, an air pressure sensor, a magnetic sensor, a position sensor (global positioning system (GPS)), or a proximity sensor in addition to the sensors described above. The functions of the sensors can be intuitively deduced by those skilled in the art from the names thereof, and thus detailed descriptions thereof may be omitted.

According to one embodiment, the output unit may output information about the state of the aerosol-generating device 1 to provide the same to the user. The output unit may include, but is not limited to, a display, a haptic unit, and/or a sound output unit. For example, information about the aerosol-generating device 1 may include a charging/discharging state of the power supply 130 of the aerosol-generating device 1, an operational state of the source unit 20 or the radiating unit 30, an insertion/removal state of the aerosol-generating article and/or the cartridge, a mounting/removal state of the cap, or a state in which the use of the aerosol-generating device 1 is restricted (e.g., detection of an abnormal object). The display may visually provide the information about the state of the aerosol-generating device 1 to the user. For example, the display may include a light-emitting diode (LED), a liquid crystal display panel (LCD), and an organic light-emitting diode panel (OLED). If the display includes a touchpad, the display may also be used as an input unit. The haptic unit may haptically provide the information about the aerosol-generating device 1 to the user. For example, the haptic unit may include a vibration motor, a piezoelectric element, and an electrical stimulation device. The sound output unit may audibly provide the information about the aerosol-generating device 1 to the user. For example, the sound output unit may convert an electrical signal into an acoustic signal and may output the acoustic signal to the outside.

According to one embodiment, the input unit may receive information input from the user. For example, the input unit 15 may include a touch panel, a button, a keypad, a dome switch, a jog wheel, and a jog switch.

According to one embodiment, the memory may be hardware storing various pieces of data processed in the aerosol-generating device 1. The memory may store data processed and to be processed by the processor 170. For example, the memory may include at least one type of storage medium among a flash memory type memory, a hard disk type memory, a multimedia card micro type memory, a card type memory (e.g., secure digital (SD) or extreme digital (XD) memory), a random access memory (RAM), a static random access memory (SRAM), a read-only memory (ROM), an electrically erasable programmable read-only memory (EEPROM), a programmable read-only memory (PROM), a magnetic memory, a magnetic disk, and an optical disc. For example, the memory may store data on an operation time of the aerosol-generating device 1, the maximum number of puffs, the current number of puffs, at least one temperature profile, and the user's smoking pattern.

According to one embodiment, the communication unit may include at least one component for communication with other electronic devices (e.g., a portable electronic device). For example, the communication unit may include a Bluetooth communication unit, a Bluetooth low energy (BLE) communication unit, a near-field communication unit, a wireless local area network (WLAN) communication unit, a Zigbee communication unit, an infrared data association (IrDA) communication unit, a wireless fidelity (Wi-Fi) direct (WFD) communication unit, an ultra-wideband (UWB) communication unit, an Ant+ communication unit, a cellular network communication unit, an Internet communication unit, and a computer network (e.g., LAN or wide area network (WAN)) communication unit.

According to one embodiment, the processor 170 may control the amplification rate of the source unit 20 (e.g., the power amplifier 230) to control the temperature of the insertion space or the aerosol-generating article. The processor 170 may control the amplification rate of the source unit 20 (e.g., the power amplifier 230) based on the temperature of the insertion space or the aerosol-generating article, sensed using the temperature sensor. The processor 170 may control the amplification rate of the source unit 20 (e.g., the power amplifier 230) based on the temperature profile and/or the power profile stored in the memory.

In addition, the processor 170 may control the supply of power from the power supply 130 to the cartridge heater to control the temperature of the cartridge heater. The processor 170 may control the temperature of the cartridge heater and/or power supplied to the cartridge heater based on the temperature of the cartridge heater detected by the temperature sensor. The processor 170 may control the temperature of the cartridge heater and/or power supplied to the cartridge heater based on the temperature profile and/or the power profile stored in the memory.

According to one embodiment, the processor 170 may prevent the insertion space, the aerosol-generating article, and/or the cartridge heater from overheating. For example, the processor 170 may control, based on the temperature of the insertion space, the aerosol-generating article, and/or the cartridge heater exceeding a preset limit temperature, operation of the power conversion circuit such that the amount of power supplied to the source unit 20 or the cartridge heater is reduced or the supply of power to the source unit 20 or the cartridge heater is interrupted.

According to one embodiment, the processor 170 may control the supply of power to the source unit 20 or the cartridge heater based on a result of detection by the sensor unit.

According to one embodiment, the processor 170 may control the supply of power to the source unit 20 or the cartridge heater based on insertion and/or removal of the aerosol-generating article into and/or from the insertion space. For example, upon determining that the aerosol-generating article has been inserted into the insertion space using the insertion detection sensor, the processor 170 may perform control such that power is supplied to the source unit 20 or the cartridge heater. Upon determining that the aerosol-generating article has been removed from the insertion space using the insertion detection sensor, the processor 170 may interrupt the supply of power to the source unit 20 or the cartridge heater. The processor 170 may determine that the aerosol-generating article has been removed from the insertion space when the temperature of the insertion space or the aerosol-generating article is equal to or higher than a limit temperature or when the temperature change slope of the insertion space or the aerosol-generating article is equal to or greater than a preset slope.

According to one embodiment, the processor 170 may control, based on the state of the aerosol-generating article, a power supply time and/or the amount of power supplied to the source unit 20 or the cartridge heater. For example, upon determining that the aerosol-generating article is in an overly moist state using the overly moist state detection sensor, the processor 170 may increase a time during which power is supplied to the source unit 20 or the cartridge heater (e.g., a preheating time).

According to one embodiment, the processor 170 may control the supply of power to the source unit 20 or the cartridge heater based on whether the aerosol-generating article is being reused. For example, upon determining that the aerosol-generating article has already been used, the processor 170 may interrupt the supply of power to the source unit 20 or the cartridge heater.

According to one embodiment, the processor 170 may control the supply of power to the source unit 20 or the cartridge heater based on whether the cartridge has been coupled and/or removed. For example, upon determining that the cartridge has been removed using the cartridge detection sensor, the processor 170 may interrupt the supply of power to the source unit 20 or the cartridge heater or may perform control such that power is not supplied to the source unit 20 or the cartridge heater.

According to one embodiment, the processor 170 may control the supply of power to the source unit 20 or the cartridge heater based on whether the aerosol-generating substance in the cartridge has been exhausted. For example, upon determining that the temperature of the cartridge heater exceeds a limit temperature during preheating of the cartridge heater (i.e., in the preheating section), the processor 170 may determine that the aerosol-generating substance in the cartridge has been exhausted. Upon determining that the aerosol-generating substance in the cartridge has been exhausted, the processor 170 may interrupt the supply of power to the source unit 20 or the cartridge heater.

According to one embodiment, the processor 170 may control the supply of power to the source unit 20 or the cartridge heater based on whether use of the cartridge is possible. For example, upon determining, based on data stored in the memory, that the current number of puffs is equal to or greater than the maximum number of puffs set for the cartridge, the processor 170 may determine that use of the cartridge is impossible. Alternatively, when a total time period during which the cartridge heater is heated is equal to or longer than a preset maximum time period or when the total amount of power supplied to the cartridge heater is equal to or greater than a preset maximum amount of power, the processor 170 may determine that use of the cartridge is impossible. In this case, the processor 170 may interrupt the supply of power to the source unit 20 or the cartridge heater or may perform control such that power is not supplied to the source unit 20 or the cartridge heater.

According to one embodiment, the processor 170 may control the supply of power to the source unit 20 or the cartridge heater based on the user's puff. For example, the processor 170 may determine whether a puff occurs and/or the intensity of a puff using the puff sensor. When the number of puffs reaches a preset maximum number of puffs and/or when no puff is detected for a preset time period or longer, the processor 170 may interrupt the supply of power to the source unit 20 or the cartridge heater. When a puff is detected, the processor 170 may control the supply of power to the source unit 20 or the cartridge heater.

According to one embodiment, the processor 170 may control the supply of power to the source unit 20 or the cartridge heater based on whether the aerosol-generating article (or the cartridge) is authentic and/or the type of the aerosol-generating article (or the cartridge). For example, the processor 170 may determine whether the aerosol-generating article is authentic and/or may determine the type of the aerosol-generating article using the cigarette identification sensor. In an example, upon determining that the aerosol-generating article (or the cartridge) is inauthentic, the processor 170 may interrupt the supply of power to the source unit 20 or the cartridge heater. Upon determining that the aerosol-generating article (or the cartridge) is authentic, the processor 170 may control (e.g., commence) the supply of power to the source unit 20 or the cartridge heater. In another example, the processor 170 may control the supply of power to the source unit 20 or the cartridge heater differently depending on the type of the aerosol-generating article (or the cartridge). In more detail, upon determining that the aerosol-generating article (or the cartridge) is a first aerosol-generating article (or a first cartridge), the processor 170 may control the amplification rate of the source unit 20, or the temperature of the cartridge heater and/or power based on a first temperature profile (or a first power profile), and upon determining that the aerosol-generating article (or the cartridge) is a second aerosol-generating article (or a second cartridge), the processor 170 may control the amplification rate of the source unit 20, or the temperature of the cartridge heater and/or power based on a second temperature profile (or a second power profile).

According to one embodiment, the processor 170 may control the output unit based on a result of detection by the sensor unit. For example, when the number of puffs counted using the puff sensor reaches a preset number, the processor 170 may control the output unit to visually, haptically, and/or audibly provide information that operation of the aerosol-generating device 1 will end soon. For example, the processor 170 may control the output unit to visually, haptically, and/or audibly provide information about the temperature of the insertion space, the aerosol-generating article, or the cartridge heater.

According to one embodiment, based on occurrence of a predetermined event, the processor 170 may store a history of the corresponding event in the memory and may update the history. For example, the event may include events performed in the aerosol-generating device 1, such as detection of insertion of the aerosol-generating article, commencement of heating of the aerosol-generating article, detection of puff, termination of puff, detection of overheating, detection of application of overvoltage to the cartridge heater, termination of heating of the aerosol-generating article, on/off operation of the aerosol-generating device 1, commencement of charging of the power supply 130, detection of overcharging of the power supply 130, and termination of charging of the power supply 130. For example, the history of the event may include the occurrence date and time of the event and log data corresponding to the event. For example, when the predetermined event is detection of insertion of the aerosol-generating article, the log data corresponding to the event may include data on a value detected by the insertion detection sensor. For example, when the predetermined event is detection of overheating of the cartridge heater, the log data corresponding to the event may include data on the temperature of the cartridge heater, the voltage applied to the cartridge heater, and the current flowing through the cartridge heater.

According to one embodiment, the processor 170 may control the communication unit to form a communication link with an external device such as a user's mobile terminal.

According to one embodiment, upon receiving data on authentication from an external device via the communication link, the processor 170 may release restriction on use of at least one function (e.g., a heating function) of the aerosol-generating device 1. For example, the data on authentication may include the user's birthday, an identification number uniquely identifying the user, and whether authentication is completed by the user.

According to one embodiment, the processor 170 may transmit data on the state of the aerosol-generating device 1 (e.g., remaining capacity of the power supply 130 and operation mode) to the external device via the communication link. The transmitted data may be output through a display or the like of the external device.

According to one embodiment, upon receiving a request to search for the location of the aerosol-generating device 1 from the external device via the communication link, the processor 170 may control the output unit to perform an operation corresponding to location search. For example, the processor 170 may perform control such that the haptic unit generates vibration or the display outputs objects corresponding to location search and termination of search.

According to one embodiment, upon receiving firmware data from the external device via the communication link, the processor 170 may perform firmware update.

According to one embodiment, the processor 170 may transmit data on a value detected by the at least one sensor unit to an external server (not shown) via the communication link, and may receive, from the server, and store a learning model generated by learning the detected value through machine learning such as deep learning. The processor 170 may perform the operation of determining the user's puff pattern and the operation of generating the temperature profile using the learning model received from the server.

Although not shown in FIG. 1, the aerosol-generating device 1 may further include a power supply protection circuit. The power supply protection circuit may include at least one switching element, and may block an electric path to the power supply 130 in response to overcharging and/or overdischarging of the power supply 130.

The aerosol-generating article mentioned in the present disclosure may include at least one aerosol-generating rod (e.g., a medium portion) and at least one filter rod. The radiating unit 30 may be disposed to correspond to the at least one aerosol-generating rod, and may be designed differently depending on the arrangement order and/or positions of the aerosol-generating rod and the filter rod. The aerosol-generating rod may contain at least one of nicotine, an aerosol-generating substance, and an additive. For example, the aerosol-generating substance may include glycerin (e.g., vegetable glycerin (VG)) and/or propylene glycol (PG) and may also include various other substances. For example, the additive may include a flavoring agent and/or an organic acid and may also include various other substances. For example, the aerosol-generating rod may include an aerosol-generating substrate (e.g., a sheet) impregnated with a liquid non-tobacco substance (e.g., an aerosol-generating substance and/or nicotine) and/or may contain a solid tobacco substance (e.g., leaf tobacco and reconstituted tobacco). The tobacco substance may be contained in the aerosol-generating rod in various forms, such as shredded tobacco, granules, and powder. According to one embodiment, the additive of the aerosol-generating rod may include an alkaline substance. Based on the alkaline substance, nicotine contained in the tobacco substance in the aerosol-generating rod may have an alkaline pH (e.g., pH 7.0 or higher). In this case, freebase nicotine may be released from the aerosol-generating rod even at a low temperature. According to one embodiment, the aerosol-generating rod may include two or more aerosol-generating rods, each of which may contain a tobacco substance and/or a non-tobacco substance. Meanwhile, although not shown, the at least one aerosol-generating rod and the at least one filter rod may individually and/or integrally be wrapped by at least one wrapper. In the present disclosure, the aerosol-generating article may be referred to as a stick.

The cartridge mentioned in the present disclosure may contain an aerosol-generating substance having any one state among a liquid state, a solid state, a gaseous state, and a gel state. The aerosol-generating substance may include a liquid composition. For example, the liquid composition may be a liquid containing a tobacco-containing substance including a volatile tobacco flavor component or may be a liquid containing a non-tobacco substance. Meanwhile, the cartridge may include a storage part that contains the aerosol-generating substance and/or a liquid delivery part that is impregnated with (contains) the aerosol-generating substance. For example, the liquid delivery part may include a wick formed of, e.g., cotton fiber, ceramic fiber, glass fiber, or porous ceramic. The cartridge heater may be included in the cartridge in a coil-shaped structure surrounding (or wound around) the liquid delivery part or a structure contacting one side of the liquid delivery part. Alternatively, the cartridge heater may be included in the aerosol-generating device 1, which is removable from the cartridge.

As used herein, the terms “substantially”, “approximately”, “generally”, and “about” in reference to a given parameter, property, or condition may include a degree that one of ordinary skill in the art would understand that the given parameter, property, or condition is met with a small degree of variance, such as within acceptable manufacturing tolerances. For example, a parameter that is substantially met may be at least 90% met, at least 95% met, or at least 99% met.

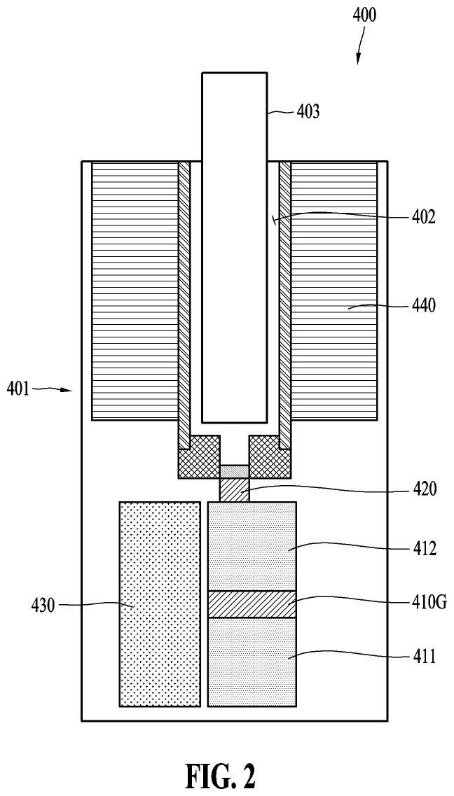

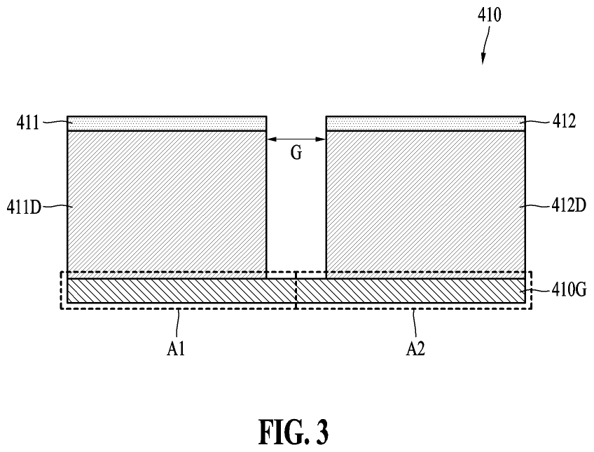

FIG. 2 is a diagram schematically illustrating an aerosol-generating device. FIG. 3 is a cross-sectional view of a printed circuit board.

Referring to FIGS. 2 and 3, an aerosol-generating system 400 may include an aerosol-generating device 401 (e.g., the aerosol-generating device 1 of FIG. 1) and an aerosol-generating article 403. The aerosol-generating device 401 may be configured to heat the aerosol-generating article 403. The aerosol-generating device 401 may include a cavity 402 (e.g., an insertion space) configured to accommodate the aerosol-generating article 403.

The aerosol-generating device 401 may include a printed circuit board 410. The printed circuit board 410 may include a ground layer 410G. The ground layer 410G may be a grounding structure of the printed circuit board 410. The ground layer 410G may be common grounding of circuits of the printed circuit board 410. The ground layer 410G may include a conductive material (e.g., copper, etc.). The ground layer 410G may be configured such that another component (e.g., a first dielectric 411D) of the printed circuit board 410 is disposed on the ground layer 410G. The diagram illustrates that the ground layer 410G is a single layer, but embodiments are not limited thereto, and the ground layer 410G may include a plurality of layers. The ground layer 410G may include a first region A1 and a second region A2 that is different from the first region A1.

The printed circuit board 410 may include the first dielectric 411D disposed on the first region A1 and a source layer 411 (e.g., the source unit 20 of FIG. 1) disposed on the first dielectric 411D and having an antenna pattern. The source layer 411 may be configured to generate an RF signal.

The relative permittivity of the first dielectric 411D may be relatively small. For example, the relative permittivity of the first dielectric 411D may be less than the relative permittivity of a second dielectric 412D. The relative permittivity of the first dielectric 411D may be about 3.5 or less, about 3.48 or less, about 3.4 or less, about 3.0 or less, about 2.7 or less, about 2.6 or less, about 2.36 or less, about 2.25 or less, or about 2.2 or less. When the relative permittivity of the first dielectric 411D is relatively large (e.g., when the relative permittivity exceeds 3.5), a signal transmission loss may be large, energy efficiency may be reduced, or temperature stability may deteriorate. Therefore, it may be appropriate that the relative permittivity of the first dielectric 411D is relatively small (e.g., the relative permittivity is 3.5 or less).

The relative permittivity of the first dielectric 411D may be about 2.0 or more, about 2.1 or more, or about 2.2 or more. When the relative permittivity of the first dielectric 411D is too small (e.g., when the relative permittivity is less than 2.0), the size of the printed circuit board 410 may increase, a signal may disperse, or mechanical stability may deteriorate. Therefore it may be appropriate that the relative permittivity of the first dielectric 411D is not too small (e.g., the relative permittivity is 2.0 or more).

The printed circuit board 410 may include the second dielectric 412D disposed on the second region A2 and a control layer 412 (e.g., the controller 10 of FIG. 1) disposed on the second dielectric 412D and separated from the source layer 411 by a gap G. The control layer 412 may be configured to control the source layer 411 to generate an RF signal. The control layer 412 may be spaced apart from the source layer 411, so thermal influence on each other may be reduced. The source layer 411 and the control layer 412 may be physically separated from each other, but the control layer 412 may be configured to control the source layer 411 through a signal.

The second dielectric 412D may be separated from the first dielectric 411D by a gap G. The diagram illustrates that the gap G between the first dielectric 411D and the second dielectric 412D is the same as the gap G between the source layer 411 and the control layer 412, but embodiments are not limited thereto, and the gap G between the first dielectric 411D and the second dielectric 412D may be different from the gap G between the source layer 411 and the control layer 412.

The aerosol-generating device 401 may include a radiating element 420 (e.g., the radiating unit 30 of FIG. 1) configured to radiate the RF signal generated by the source layer 411 to the aerosol-generating article 403 or the cavity 402. The RF signal generated by the source layer 411 may be transmitted from the radiating element 420.

The aerosol-generating device 401 may include a battery 430 (e.g., the power supply 130) configured to supply power for the operation of the aerosol-generating device 401.

The aerosol-generating device 401 may include a resonance structure 440 that at least partially encloses the cavity 402 (e.g., that may correspond to the resonating unit in the description provided with reference to FIG. 1). Alternatively, the resonance structure 440 may be a structure for defining the cavity 402 in the resonance structure 440. The resonance structure 440 may absorb the RF signal radiated from the radiating element 420 and generate resonance. The resonance structure 440 may include a dielectric configured to generate resonance. Resonance of the dielectric may indicate that resonance is generated by an RF signal in the resonance structure 440, thereby forming an alternating electromagnetic field. That is, the resonance structure 440 may resonate and generate the alternating electromagnetic field by the RF signal. The resonance structure 440 may apply the alternating electromagnetic field to the aerosol-generating article 403 through the resonance of the dielectric. For example, when the aerosol-generating article 403 is disposed adjacent to or spaced apart from the resonance structure 440, the resonance structure 440 may apply the alternating electromagnetic field to the aerosol-generating article 403.

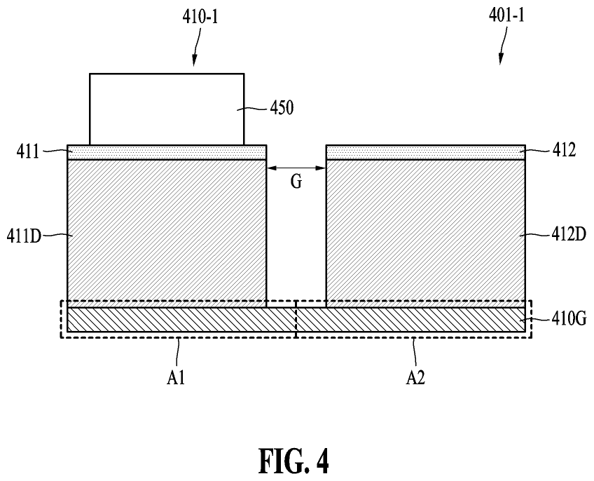

FIG. 4 is a cross-sectional view of a printed circuit board and a heat sink.

Referring to FIG. 4, an aerosol-generating device 401-1 may include a printed circuit board 410-1 (e.g., the printed circuit board 410 of FIGS. 2 and 3). The aerosol-generating device 401-1 may include a heat sink 450 disposed on the source layer 411. The heat sink 450 may be configured to emit heat generated from the source layer 411. The heat sink 450 may emit heat to keep the temperature of the printed circuit board 410-1 less than or equal to an appropriate temperature.

The heat sink 450 may include a material having excellent thermal conductivity. For example, the heat sink 450 may include a metal material (e.g., aluminum, copper, etc.). For example, the heat sink 450 may include graphite. The diagram illustrates that the heat sink 450 is disposed on the source layer 411, but embodiments are not limited thereto, and the heat sink 450 may be disposed at a different position and increase the heat emission efficiency of the printed circuit board 410-1.

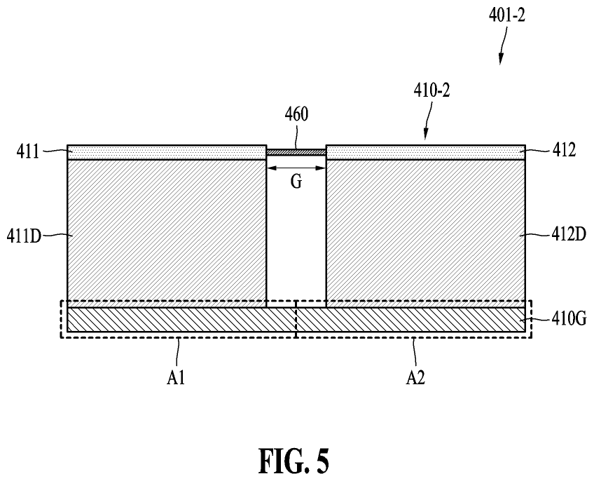

FIG. 5 is a cross-sectional view of a printed circuit board and a transmission line.

Referring to FIG. 5, an aerosol-generating device 401-2 may include a printed circuit board 410-2 (e.g., the printed circuit board 410 of FIGS. 2 and 3 or the printed circuit board 410-1 of FIG. 4). The aerosol-generating device 401-2 may include a transmission line 460 configured to connect the source layer 411 to the control layer 412. The transmission line 460 may be configured to transmit a signal between the source layer 411 and the control layer 412. The transmission line 460 may be designed as a structure for efficiently transmitting the signal between the source layer 411 and the control layer 412.

Some embodiments of the disclosure described above or other embodiments are not mutually exclusive or distinct from each other. Some embodiments of the disclosure described above or other embodiments may be used jointly or combined with each other in configuration or function.

For example, a configuration A described in one embodiment and/or drawing and a configuration B described in another embodiment and/or drawing may be combined with each other. That is, although the combination between the configurations is not directly described, the combination is possible except in cases where it is described that the combination is impossible.

The above detailed description should not be construed in all aspects as limiting and should be considered illustrative. The scope of the present disclosure should be determined by rational interpretation of the appended claims, and all variations within the scope of equivalents of the present disclosure are included in the scope of the present disclosure.

What is claimed is:

1. An aerosol-generating device comprising:
a cavity configured to accommodate an aerosol-generating article;
a radiating element configured to radiate a radio frequency (RF) signal to the cavity; and
a printed circuit board,
wherein the printed circuit board comprises:
a ground layer comprising a first region and a second region that is different from the first region;
a first dielectric disposed on the first region;
a second dielectric disposed on the second region;
a source layer disposed on the first dielectric and having an antenna pattern; and
a control layer disposed on the second dielectric, separated from the source layer by a gap, and configured to control the source layer to generate an RF signal, and
wherein relative permittivity of the first dielectric is less than relative permittivity of the second dielectric.

2. The aerosol-generating device of claim 1, wherein the relative permittivity of the first dielectric is about 2.0 or more and about 3.5 or less.

3. The aerosol-generating device of claim 1, further comprising:
a heat sink disposed on the source layer.

4. The aerosol-generating device of claim 3, wherein the heat sink comprises graphite.

5. The aerosol-generating device of claim 1, further comprising:
a transmission line configured to connect the source layer to the control layer.

6. The aerosol-generating device of claim 1, further comprising:
a resonance structure at least partially enclosing the cavity.

7. An aerosol-generating system comprising:
an aerosol-generating article; and
an aerosol-generating device configured to heat the aerosol-generating article,
wherein the aerosol-generating device comprises:
a cavity configured to accommodate the aerosol-generating article;
a radiating element configured to radiate a radio frequency (RF) signal to the cavity; and
a printed circuit board,
wherein the printed circuit board comprises:
a ground layer comprising a first region and a second region that is different from the first region;
a first dielectric disposed on the first region;
a second dielectric disposed on the second region;
a source layer disposed on the first dielectric and having an antenna pattern; and
a control layer disposed on the second dielectric, separated from the source layer by a gap, and configured to control the source layer to generate an RF signal, and
wherein relative permittivity of the first dielectric is less than relative permittivity of the second dielectric.

8. The aerosol-generating system of claim 7, wherein the relative permittivity of the first dielectric is about 2.0 or more and about 3.5 or less.

9. The aerosol-generating system of claim 7, wherein the aerosol-generating device further comprises a heat sink disposed on the source layer.

10. The aerosol-generating system of claim 9, wherein the heat sink comprises graphite.

11. The aerosol-generating system of claim 7, wherein the aerosol-generating device further comprises a transmission line configured to connect the source layer to the control layer.

12. The aerosol-generating system of claim 7, wherein the aerosol-generating device further comprises a resonance structure at least partially enclosing the cavity.
